(19) United States
(12) Patent Application Publication
(10) Pub. No.: US 2008/0280231 A1
(43) Pub. Date: Nov. 13, 2008

(54) Bounce drive actuator and micromotor

(75) Inventors: Alex Horng, Kaohsiung City (TW); I-Yu Huang, Kaohsiung City (TW); Guan-Ming Chen, Kaohsiung City (TW)

Correspondence Address: BACON & THOMAS, PLLC, 625 SLATERS LANE, FOURTH FLOOR, ALEXANDRIA, VA, 22314-1176, US

(73) Assignee: Sunonwealth Electric Machine Industry Co., Ltd., Kaohsiung City (TW)

(21) Appl. No.: 11/812,409

(22) Filed: Jun. 19, 2007

(30) Foreign Application Priority Data
May 9, 2007 (TW) 96116451

(51) Int. Cl. G03F 7/20

(52) U.S. Cl. 430/312

(57) ABSTRACT

Provided is the design and fabrication of the novel bounce drive actuator (BDA) for the development of a new-type micro rotary motor. Although the scratch drive actuator (SDA) micro motor has been developed more than one decade, such device has limited commercial applications due to its shorter lifetime, high power consumption and sudden reverse rotation. In contrast, present invention proposes an innovative BDA micro rotary motor with different actuating mechanism and improved performance. Several significant investigations shown in this research present that the length of the SDA-plate is longer than 75 μm and the plate length of the BDA is less than 75 μm. Under the same driving power and frequency with SDA-based micro motor, the BDA-based micro rotary motor exhibited a consistent “reverse” rotation and a higher speed. BDA has higher flexural rigidity due to its shorter length of plate; thus, the contact area of the bending BDA-plate and the insulator substrate will substantially be reduced even under the same applied voltage as the priming value of SDA-plate. Furthermore, a novel rib and flange structure design for the improvement of lifetime (>100 hrs) and rotational speed (>30 rpm) of BDA micro motor was also demonstrated in this invention.

### FIELD OF THE INVENTION

This invention generally relates to photolithographically patterned BDA micro rotary motor for micro-electromechanical systems (MEMS) applications. This invention also relates to a new BDA actuating mechanism and performance improvements of the conventional electrostatic drive micro rotary motor. The major technology adopted in present invention is the polysilicon-based surface micromachining process of MEMS technology, with the advantages of batch fabrication, low cost and high compatibility with integrated circuit technology.

### BACKGROUND OF THE INVENTION

The development and application of miniaturization technology is the major trend of modem science. In particular, integrated circuits (IC) and microelectromechanical systems (MEMS) technologies are the rudimentary methods of the microscopic world in the recent years.

Appendix 1 shows a conventional scratch drive actuator (SDA) with precise and stepwise linear motion mechanism.

According to the descriptions of Bright and Linderman [1-2], the stepwise motion begins with the free end of SDA-plate electrostatically loaded with the snap through voltage resulting in the plate tip snapping down to touch the nitride dielectric layer. When the power increased to the priming voltage, the plate tip will be deflected enough to flatten to a zero slope at the free end. Finally, as the applied power was removed, the strain energy stored in the supporting beams, SDA-plate and bushing will pull the SDA-plate forward to complete the step.

The basic optimized dimension of the micro SDA plate has been demonstrated in the previous literatures (reported by R. J. Linderman & V. M. Bright) as 78 μm-length and 65 μm-width simulation software and experimental measurements, as shown in Appendix 2.

An implemented SDA-based micro rotary motor is shown in Appendix 3. The smallest SDA-based micro fan device in the world with dimension of 2 mm×2 mm (as shown in Appendix 4) is constructed by self-assembly micro blades and micro scratch drive actuators. Such SDA actuated micro fan is fabricated by using polysilicon based surface micromachining technology (multi-user MEMS processes, MUMPs) as Appendix 5 shows.

The conventional SDA-based micro motor or micro fan devices have limited commercial applications due to its shorter lifetime, high driving power and sudden reverse rotation. To improve such disadvantages, this invention presents an innovative BDA-based micro motor with a novel rib and flange structure design for lifetime enhancement, speed improvement, power reduction and consistent rotation.

### SUMMARY OF THE INVENTION

Provided is the design and fabrication of the novel bounce drive actuator (BDA) for development of a new-type micro rotary motor or micro fan with longer lifetime, lower drive power and consistent rotate direction. Present invention proposes an innovative bounce drive actuator with a novel rib and flange structure design for lifetime enhancement, speed improvement, power reduction and consistent rotation. The major dimensional specification of bounce drive actuator (BDA), comprising the bushing portion of the BDA-plate with aspect ratio (height/width) less than 1 and the length of the BDA-plate is shorter than 75 μm.

Compared with the conventional SDA devices, present invention provides a shorter and wider bushing structure in the BDA-plate design to increase the flexural rigidity of plate and to reduce the contact (friction) area of the bending plate and the insulator substrate under the same applied voltage as the priming value of SDA-plate. Any additional electrostatic load beyond the priming voltage can not deflect the free end of BDA-plate anymore and results in the bushing compressed and introverted. When the applied voltage was removed, the stored strain energy will bounce the actuator backward since the friction force of bushing is larger than the free end of BDA-plate.

Furthermore, a novel rib and flange structure design for the improvement of lifetime (>100 hrs) and rotational speed (>30 rpm) of BDA micro motor was also demonstrated in this invention.

### BRIEF DESCRIPTION OF THE DRAWINGS

FIG. 1 shows the main structures of conventional SDA micro motor and novel BDA micro motor from the simulated results of the L-edit software.

FIG. 2 depicts an innovative “flange” design to further enhance the structure robustness and the lifetime of BDA micro motor.

FIG. 3 illustrates the cross-sectional structure and dimension of SDA and BDA.

FIG. 4 illustrates the different actuating mechanism of SDA and BDA devices.

FIG. 5 shows the layout and cross-sectional structure designs of the BDA micro motor in present invention.

FIG. 6 illustrates the cross-section views of the main process steps of SDA micro motor.

FIG. 7 Rotary speed versus plate length of BDA and SDA micro motors.

FIG. 8 Dynamic micrographs of actuating BDA micro motors under two different drive frequency.

FIG. 9 Rotary speed versus driving frequency of BDA micro motor.

FIG. 10 illustrates a novel design of micro fan actuated by a BDA micro motor.

### BRIEF DESCRIPTION OF THE MAIN DEVICE SYMBOL

(01) Si wafer
(02) Nitride
(03) Poly Si-1
(04) Poly Si-2
(05) Poly Si-3
(06) SDA-plate
(07) Supporting beam of SDA
(08) BDA-plate
(09) Supporting beam of BDA
(10) Ring
(11) Rib
(12) Cover
(13) Flange
(14) SDA Bushing
(15) BDA Bushing
(16) Biasing pad
(17) Ground pad
(20) Si substrate
(21) Low-stress Si₃N₄
(22) Contact window of substrate
(23) Low stress in-situ doped Poly Si-1
(24) Trail
(25) Pad of anchor
(26) Low stress PSG-1
(27) Dimple window
(28) Bushing window
(29) Low stress in-situ doped Poly Si-2
(30) Rib
(31) Low stress PSG-2
(32) Dimple window
(33) Cover window
(34) Bushing window
(35) Anchor window
(36) Low stress in-situ doped Poly Si-3
(37) Dimple
(38) Supporting beam
(39) Ring
(40) Cover
(41) Bushing
(42) BDA rotor
(43) Cr/Au metal
(44) Biasing pad
(45) Ground pad
(50) BDA micro motor
(51) Micro blade
(52) Polyimide joint

### APPENDIX

Appendix 1: The conventional SDA device.
Appendix 2: Simulation results of the optimization of SDA plate length.
Appendix 3: An implemented SDA-based micro rotary motor.
Appendix 4: A miniaturized SDA-based micro fan fabricated by using MEMS technology.
Appendix 5: MEMSCAP's Multi-user MEMS processes (MUMPs).
Appendix 6: The SEM micrograph of the flange structure design for the improvement of flexural rigidity and lifetime of BDA micro motor.
Appendix 7: Rotating direction versus plate length of SDA and BDA micro motor.

### DETAILED DESCRIPTION OF THE PREFERRED EMBODIMENTS

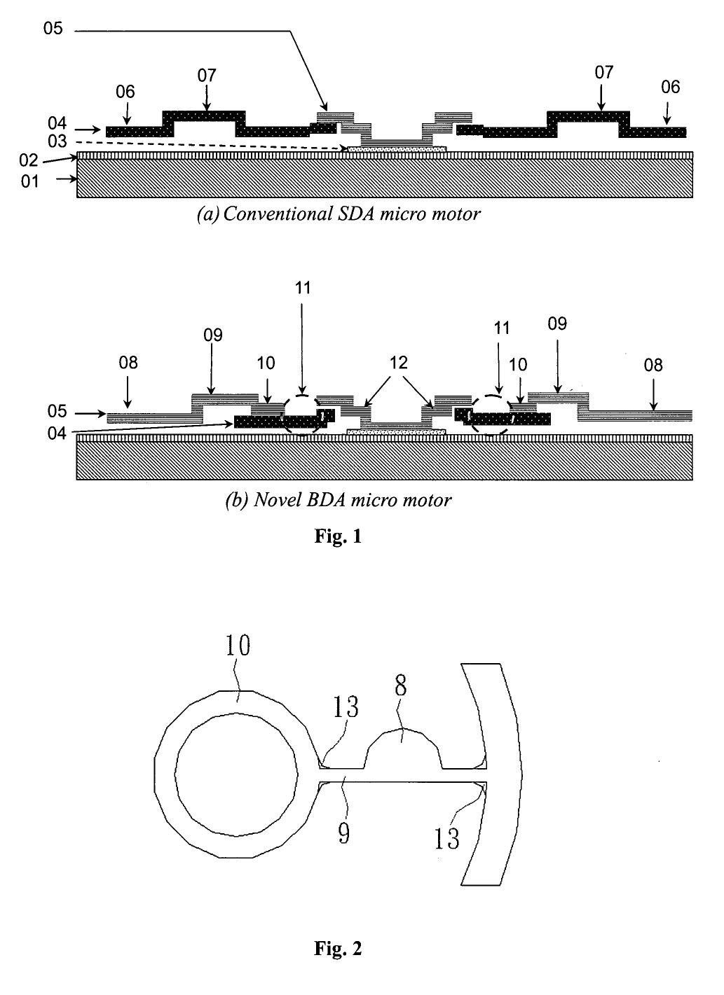

Conventional SDA micro motor has limited commercial applications due to its short lifetime, high driving power and sudden reverse rotation. FIG. 1 shows the main structures of conventional SDA micro motor and novel BDA micro motor from the simulated result of the L-Edit software. To enhance the break resistance (results from twist force) of the supporting beam (09), present invention utilizes the polysilicon-3 (05) layer to simultaneously construct the BDA-plate (08), supporting beam (09), ring (10) and the cover (12), which form a thicker “rib” structure (11) (stacked by Poly Si-2 (04) and Poly Si-3 (05) layers) adjacent to the ring (10) part; thus, the flexural rigidity and the lifetime of BDA micro motor can be improved.

FIG. 2 shows a novel “flange (13)” layout proposed in present invention. The flange design can further enhance the structure robustness of the supporting beam to further improve the yield of the BDA micro motor and reduce the crack failure under actuating situation. Appendix 6 shows SEM micrograph of the BDA micro motor with flange layout design. The novel rib and flange structure design for the improvement of lifetime (>100 hrs) and rotational speed (>30 rpm) of BDA micro motor was demonstrated in this patent.

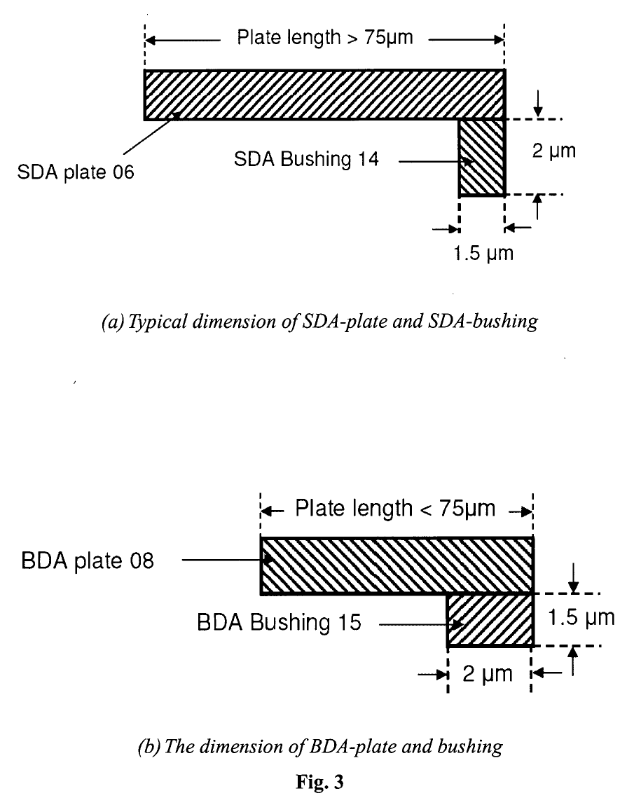

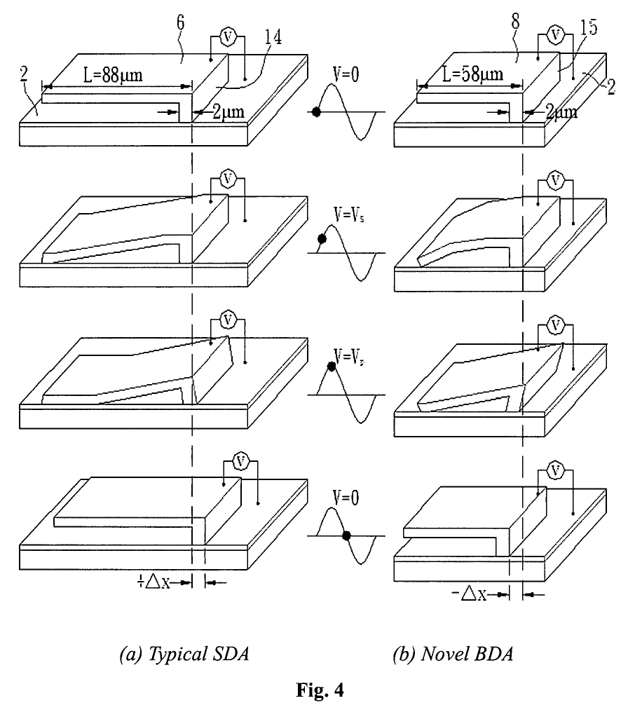

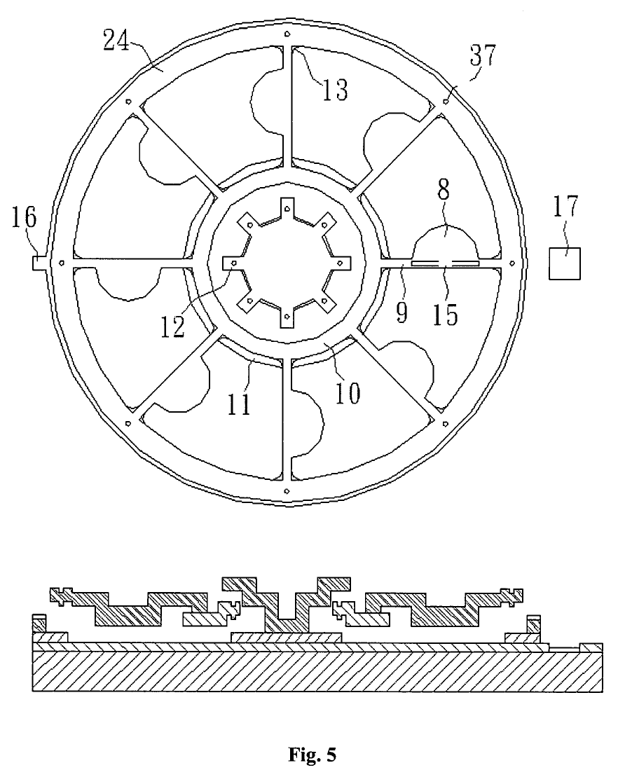

FIG. 3 illustrates the cross-sectional structure and dimension of SDA and BDA devices. It is obvious that the BDA-plate (08) has shorter length than the SDA-plate (06) and the BDA-bushing (15) is shorter and wider than the SDA-bushing (14). FIG. 4 illustrates the operating mechanism of SDA-plate (06) and BDA-plate (08) respectively. Turning to FIG. 1 and FIG. 3, according to the descriptions of Bright and Linderman, the stepwise motion begins with the free end of SDA-plate (06) electrostatically loaded with the snap through voltage resulting in the plate tip snapping down to touch the nitride (02) dielectric layer. When the power increased to the priming voltage, then the plate tip will be deflected enough to flatten to a zero slope at the free end. Finally, as the applied power was removed, the strain energy stored in the supporting beam (07), SDA-plate (06) and bushing (14) will pull the SDA-plate (06) forward to complete the step. On the other hand, BDA-plate (08) has higher flexural rigidity due to its shorter length; thus, the contact area of the bending plate and the nitride (02) insulator layer will substantially be reduced under the same applied voltage as the priming value of SDA-plate (06). Any additional electrostatic load beyond the priming voltage can not deflect the free end of BDA-plate (08) anymore and results in the bushing (15) compressed and introverted. When the applied voltage was removed, the stored strain energy will bounce the actuator backward since the friction force of the short and wide bushing (15) is larger than the free end of BDA-plate (08).

FIG. 5 shows the layout and cross-sectional structure designs of the BDA micro motor in present invention, where the rib (11) and flange (13) structure are designed to enhance the structure robustness of the supporting beam, which will further improve the yield of the BDA micro motor and reduce the crack failure under actuating situation.

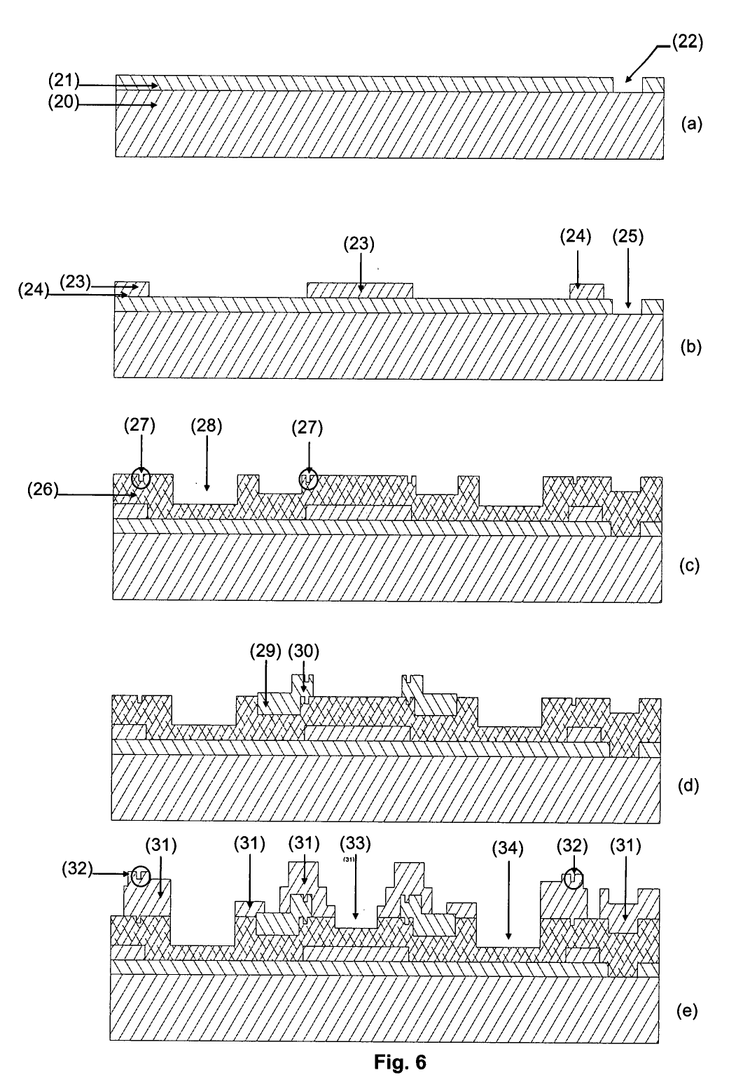

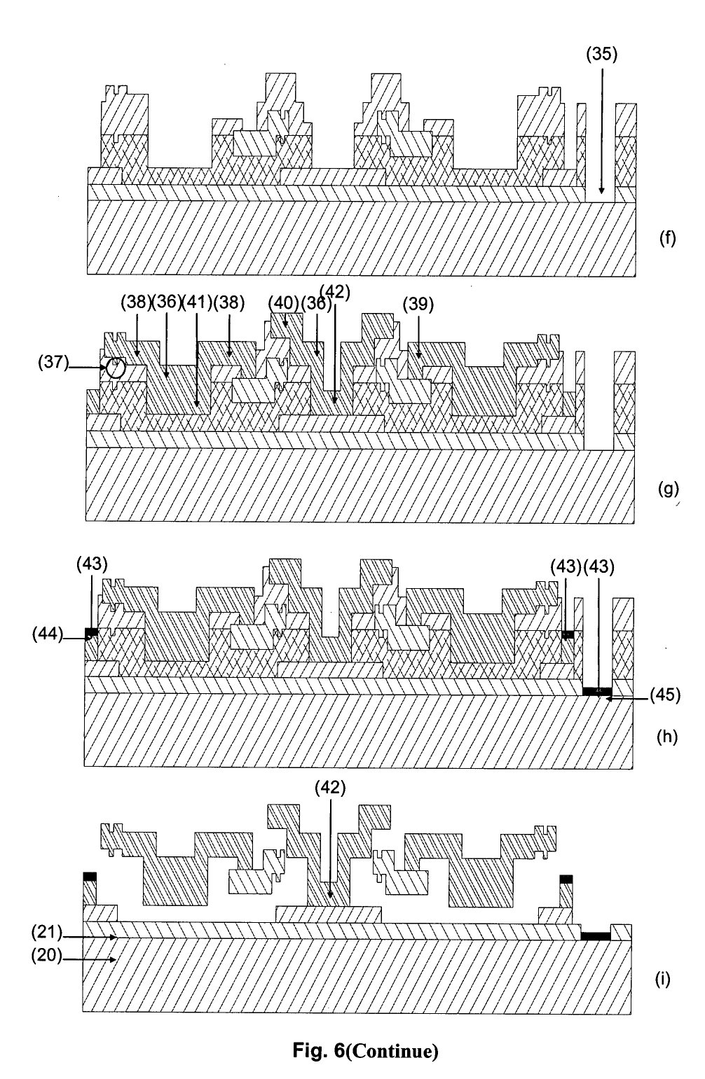

FIG. 6 shows the fabricating flow of the BDA micro motor adopted in this invention. The complete processes at least require eight photolithograph and seven thin film deposition processes. The major manufacturing technology of the present invention is the polysilicon-based surface micromachining process. The main processing steps are described in detail as follows:
(a) Photolithographically patterning the layer of the 600 nm-thick low-stress silicon nitride (21) insulator which is deposited on an ultra-low resistivity silicon substrate (20) by a LPCVD system. As FIG. 6(a) shows, at least one electrical contact window of substrate (22) can be defined in the first photolithograph and etching process.
(b) Using LPCVD system to deposit a 1.5 μm-thick low stress in-situ doped polysilicon layer (23) on or above the silicon substrate. As FIG. 6(b) shows, this invention adopts an inductive-coupling plasma (ICP) etching system to precisely define the areas of trail (24) and the pad of anchor (25) in the secondary photolithographicalling patterning process.
(c) Plasma-enhanced chemical-vapor depositing (PECVD) a 2 μm-thick low stress PSG sacrificial layer (26) on or above the substrate. To precisely control the critical dimension and enhance the etching anisotropy, present invention adopts an ICP dry etching system to pattern at least one 750 nm-depth dimple window (27) and bushing window (28) of BDA micro motor after the third photolithography process (FIG. 6(c)).
(d) Depositing a 2 μm-thick low stress in-situ doped polysilicon layer (29) on or above the substrate by using LPCVD system and patterning it to define at least one rib (30) microstructure of the BDA micro motor by using photolithographic and dry etching processes (FIG. 6(d)).
(e) Depositing a 1.5 μm-thick low stress PSG sacrificial layer (31) on or above the substrate by using PECVD system. The fifth photomask is used to pattern the areas of dimple window (32), cover window (33) and bushing window (34) of BDA micro motor as shown in FIG. 6(e).
(f) Through the sixth photolithographic and dry etching processes, present invention can further define the areas of anchor window (35) of BDA micro motor as shown in FIG. 6(f).
(g) Depositing the third 2 μm-thick low stress in-situ doped polysilicon (36) on or above the substrate by using LPCVD system and patterning it to define at least one dimple (37), supporting beam (38), ring (39), cover (40), bushing (41) and BDA rotor (42) of the BDA micro motor by using the seventh photolithograph and dry etching processes (FIG. 6(g)).
(h) Depositing a 200 nm-thick chromium and a 250 nm-thick gold metal films (43) on or above the substrate by using an E-beam evaporator deposition system. In the eighth photolithographic process, this invention utilizes a lift-off method to pattern the chromium and gold metal layers and to define at least one biasing pad (44) and ground pad (45) of the BDA micro motor (FIG. 6(h)).
(i) Under-cut etching the 1^{st} and 2^{nd} PSG sacrificial layers (26 & 31) by using a 49% HF acid solution to release the BDA rotor (42) portion of the BDA micro motor from the substrate (20). After the release process, the free standing BDA rotor (42) can rotate on the silicon nitride (21) insulator under appropriate electrostatic driving (FIG. 6(i)).

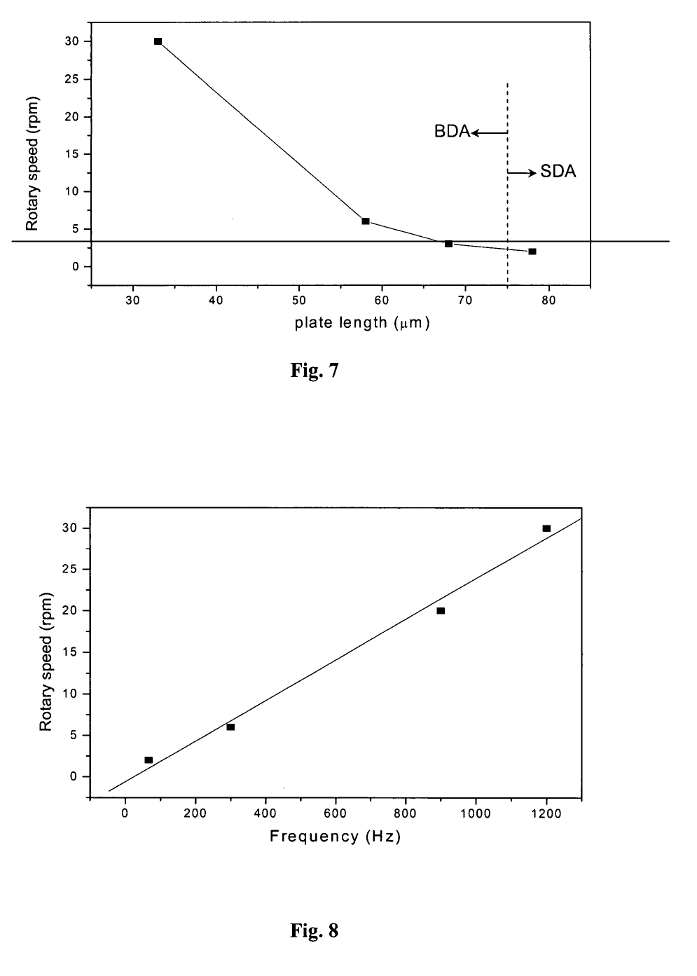

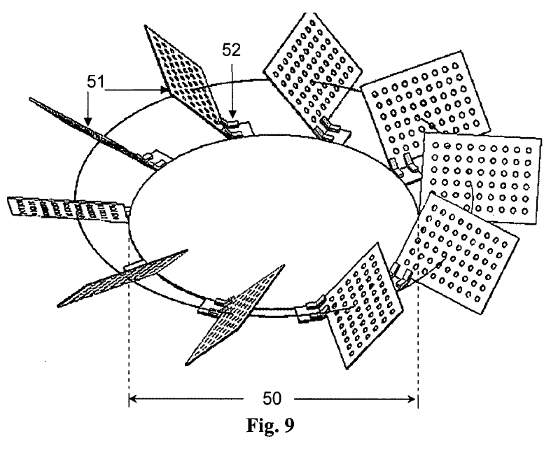

Appendix 7 shows SEM micrographs of one SDA micro motor and three BDA micro motors with different plate length design. Based on the dynamic measurements, as the length of the plate is longer than 75 μm (e.g. 78˜88 μm), the motor has SDA functions and exhibites a “forward” rotation (and sudden reverse rotation) of approximately only 1 rpm under a sinusoidal 90 Vₒ₋ₚ ac signal at frequencies 900 Hz. Once the plate length reduced to less than 75 μm (e.g. 68, 58, 33 μm), the motor has BDA functions and exhibites a consistent “reverse” rotation of approximately >30 rpm under the same power and frequency. FIG. 7 shows the corresponding rotary speed measured from four different length designs of the SDA and BDA-micro motors. Obviously, the shorter plate demonstrated a higher rotary speed under the same powered condition. FIG. 8 presents the dynamic rotating micrographs of two actuating BDA micro motor both with the same plate length and have the same half-circular shape. FIG. 9 shows the frequency response of the BDA micro motor and demonstrates the expected nearly linear increase in rotation speed of BDA micro motor with driving frequency.

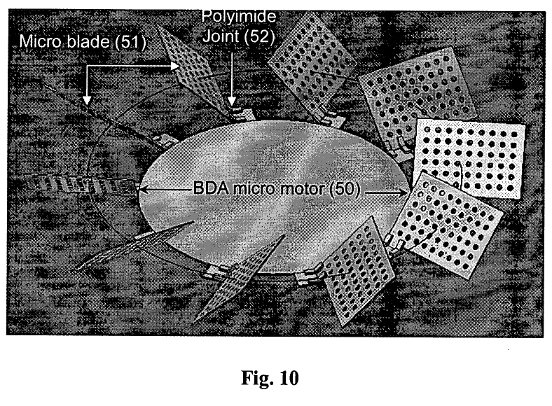

FIG. 10 illustrates a novel design of a possible application of BDA micro motor (50), the BDA micro fan, which is constructed by the BDA micro motor (50) and eight polyimide self-assembly micro-blades (51). The basic actuating mechanism of polyimide self-assembling utilizes the surface tension force of the polyimide elastic joint (52) generated during the high-temperature reflow process to lift the structural layer.

What is claimed is:

1. The dimensional specification of bounce drive actuator (BDA), comprising:
a. A bushing portion of the BDA-plate with aspect ratio (height/width) less than 1;
b. A length of the BDA-plate is shorter than 75 μm.

2. Design the layout of micro rotary motor under the dimensional criteria mentioned in claim 1, a bounce-drive micro rotary motor can be demonstrated in present invention. BDA-plate has higher flexural rigidity due to its shorter length; thus, the contact area of the bending plate and the nitride insulator will substantially be reduced under the same applied priming voltage of SDA-plate. Any additional electrostatic load beyond the priming voltage can not deflect the free end of BDA-plate anymore and results in the bushing compressed and introverted. When the applied voltage was removed, the stored strain energy will bounce the actuator backward since the friction force of the short and wide bushing is larger than the free end.

3. A novel structure design of the said BDA micro motor described in claim 2, comprising the said rib and flange structure designs were firstly adopted in the design and fabrication of BDA-based micro motor for the improvement of lifetime (>100 hrs) and rotational speed (>30 rpm).

4. A method for forming a BDA-based micro rotary motor comprising the steps of:
a. depositing a first layer of silicon nitride insulator material on or over a silicon substrate, the silicon nitride insulator having a little tensile stress and a low friction coefficient;
b. photolithographically patterning the layer of low stress nitride insulating material to form at least one electrical contact window of the silicon substrate;
c. depositing the second layer of material on or above the silicon substrate, which is an in-situ doped polysilicon material having a very low stress;
d. photolithographically patterning the 1^{st} low stress in-situ doped polysilicon structural layer to form at least one trail of the BDA micro rotary motor and one pad of anchor;
e. depositing the third layer of material on or above the silicon substrate, which is a phosphosilicate (PSG) material having a low stress and acts as a sacrificial layer of the structural layer of the BDA micro rotary motor;
f. photolithographically patterning the 1^{st} low stress PSG sacrificial layer to define at least one bushing window and one dimple window of the BDA micro motor;
g. depositing the fourth layer on or over the 1^{st} PSG sacrificial layer, which is an in-situ doped polysilicon material having a very low stress;
h. photolithographically patterning the 2^{nd} in-situ doped low stress polysilicon layer to define at least one rib microstructure portion of the BDA micro rotary motor;
i. depositing the fifth layer of material on or over the rib and a potion of the 1^{st} PSG sacrificial layer, which is a phosphosilicate (PSG) material having a low stress and acts as a 2^{nd} sacrificial layer of the structural layer of BDA micro rotary motor;
j. photolithographically patterning the 2^{nd} PSG sacrificial layer to define at least one dimple window and one bushing window;
k. photolithographically patterning the 1^{st} and 2^{nd} PSG sacrificial layer to define at least one cover window of the BDA micro motor;
l. depositing the sixth layer of material on or over a portion of the rib and a portion of the 2^{nd} PSG sacrificial layer, which is an in-situ doped polysilicon material having a very low stress and acts as a main structural layer of the BDA micro rotary motor;
m. photolithographically patterning the 3^{rd} low stress polysilicon structural layer to define the cover portion and at least one BDA rotor portion of the micro rotary motor;
n. depositing the seventh layer of material on or over the 3^{rd} low stress polysilicon layer and a portion of the 2^{nd} PSG sacrificial layer, which is composed of chromium and gold metal layers;
o. photolithographically patterning the chromium and gold metal layers to define the biasing and ground pads of the BDA micro rotary motor;
p. under-cut etching the 1^{st} and 2^{nd} PSG sacrificial layers to release the BDA rotor portion of the BDA micro motor from the substrate, the cover and trail portions of the BDA micro motor remaining fixed to the substrate. After the release process, the free standing BDA rotor can rotate on the silicon nitride insulator under appropriate electrostatic driving.

5. The method of claim 4, wherein the step of depositing the layer of the insulator material comprises the step of deposition and post annealing processes by using a low-pressure chemical vapor deposition (LPCVD) system. The said low stress silicon nitride insulator means its stress must be controlled under 250 MPa.

6. The method of claim 4, wherein the electrical contact window of the silicon substrate is reserved for the electrical contact of metal layer and the silicon substrate. In the driving of the BDA micro motor, the said silicon substrate acts as a ground electrode and a mechanical supporting.

7. The method of claim 4, wherein the step of depositing the layer of the low stress in-situ doped polysilicon material comprises the step of deposition, in-situ doping and post annealing processes in a low-pressure chemical vapor deposition (LPCVD) system. Each sub-process of this step is proceeding under different pressure, gas flow and temperature. The said low stress polysilicon thin structural film means its stress must be controlled under 200 MPa.

8. The method of claim 4, wherein the step of depositing the layer of the low stress PSG sacrificial material comprises the step of deposition and post annealing processes by using a plasma-enhanced chemical vapor deposition (PECVD) system. The said low stress PSG sacrificial material means its stress must be controlled under 300 MPa.

9. The method of claim 4, wherein the step of depositing the layer of the sacrificial material comprises the step of depositing a low stress phosphosilicate (PSG).

10. A method for forming a BDA-based micro fan comprising the steps of:
a. fabricating the BDA micro motor following the processes described in claim 1 except the last releasing process;
b. spin coating a polyimide thin film on or over the said 3^{rd} low stress polysilicon structural layer of the BDA micro rotary motor;
c. photolithographically patterning and etching an elastic joint form on the said polyimide thin film;
d. under-cut etching the 1^{st} and 2^{nd} PSG sacrificial layers to release the BDA rotor portion and the micro blade portion of the BDA micro fan from the substrate, the cover and trail portions of the BDA micro motor remaining fixed to the substrate;
e. carrying out a reflow process to result in contraction of the said polyimide elastic joint to rotate and lift a pre-defined micro blade portion, the lift angle of micro blade portion can be controlled by tuning the reflow temperature of polyimide layer;
After the structure releasing and polyimide curing process, the free standing BDA micro fan can rotate on the silicon substrate under appropriate electrostatic driving.

11. The method of claim 10 wherein the method of forming the lifted micro blade results in a polyimide self-assembling microstructure. The basic actuating mechanism of polyimide self-assembling utilizes the surface tension force of the polyimide elastic joint generated during the high-temperature reflow process to lift the structural layer.

12. The method of claim 10 wherein the etching step is an under-cut etching process.

13. The method of claim 10 wherein the step of etching is a selective etching process, the step uses a diluted HF acid which etches the PSG sacrificial layers much faster than the polysilicon structural layer.
